(19) United States
(12) Patent Application Publication
(10) Pub. No.: US 2025/0351309 A1
(43) Pub. Date: Nov. 13, 2025

(54) ENCLOSURE FOR THERMAL MANAGEMENT OF A SYSTEM

(71) Applicant: Micron Technology, Inc., Boise, ID (US)

(72) Inventors: Joseph Soares, Lakewood, CO (US); Donald Lee, Boise, ID (US); Jonathan R. Hinkle, Raleigh, NC (US)

(21) Appl. No.: 19/202,568

(22) Filed: May 8, 2025

Related U.S. Application Data
(60) Provisional application No. 63/646,317, filed on May 13, 2024.

(51) Int. Cl. H05K 7/20

(52) U.S. Cl. CPC H05K 7/20772

(57) ABSTRACT

An enclosure to at least partially enclose a memory sub-system within an interior of the enclosure. The enclosure includes a first enclosure portion including a first recessed portion. The enclosure further includes a first set of one or more heat pipes arranged within the first recessed portion. The enclosure further includes a second enclosure portion including a second recessed portion. The enclosure further includes a second set of one or more heat pipes arranged within the second recessed portion, where the first enclosure portion and the second enclosure portion form a cavity to house a memory sub-system, and where heat generated by the memory sub-system is conducted via the first set of one or more heat pipes and the second set of one or more heat pipes to a first end of the enclosure.

### CROSS-REFERENCE TO RELATED APPLICATION

This application claims the benefit of U.S. Provisional Application No. 63/646,317, titled “Enclosure for Thermal Management of a System”, filed May 13, 2024, which is hereby incorporated herein by reference in its entirety.

### TECHNICAL FIELD

Embodiments of the disclosure relate generally to memory sub-systems, and more specifically, relate to an enclosure providing thermal management of a system (e.g., a memory sub-system).

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices. A memory sub-system can be housed within an enclosure, that is optionally mounted on a rack, for example, as part of or with a rackmount server, optimizing space efficiency and simplifying maintenance in data centers and server environments. These enclosures may conform to standardized rack dimensions and provide durable physical protection for the internal system (e.g., components of a memory sub-system) along with electromagnetic shielding. Additionally, an enclosure can be equipped with features for thermal management of the components housed within the enclosure.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system housed within an enclosure, in accordance with one or more embodiments of the present disclosure.

FIG. 2A illustrates an example enclosure housing a memory sub-system, in accordance with one or more embodiments of the present disclosure.

FIG. 2B illustrates a cross-section view of an example enclosure, according to one or more embodiments of the present disclosure.

FIG. 3A illustrates an expanded perspective view of an enclosure and system to enclose therein, in accordance with one or more embodiments of the present disclosure.

FIG. 3B illustrates a perspective view of an example first enclosure portion of an enclosure, in accordance with one or more embodiments of the present disclosure.

FIG. 4A illustrates an example enclosure in contact with a cold plate and a connector of a computing system, in accordance with one or more embodiments of the present disclosure.

FIG. 4B illustrates an example cold plate configured to contact an enclosure, in accordance with one or more embodiments of the present disclosure.

FIG. 5 illustrates a set of example enclosures, in accordance with one or more embodiments of the present disclosure.

FIG. 6 is a block diagram of an example computer system in which embodiments of the present disclosure may operate.

### DETAILED DESCRIPTION

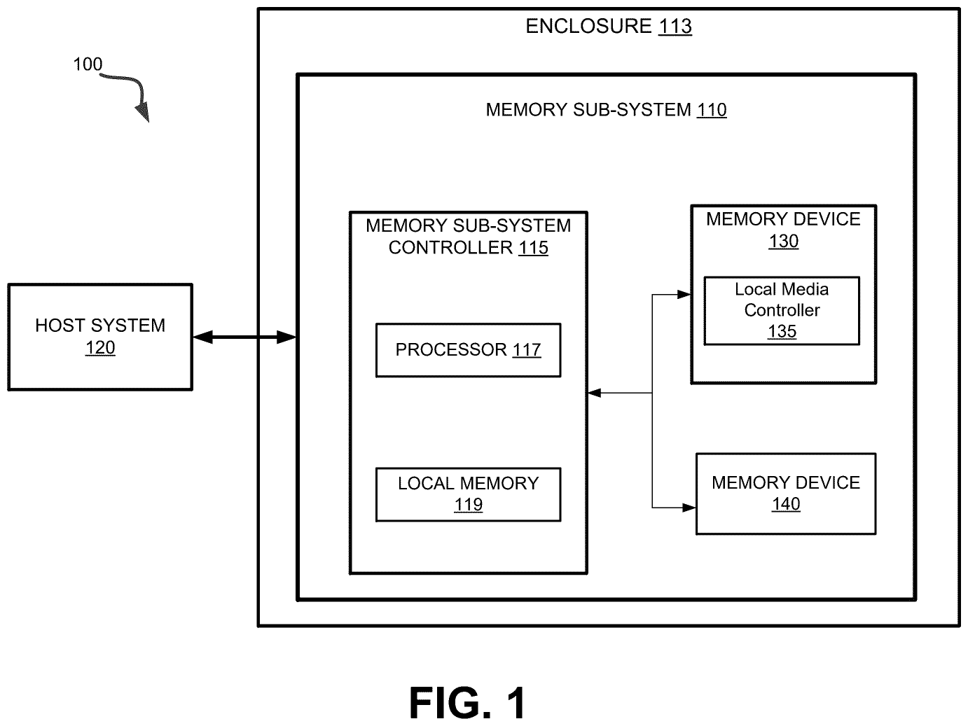

Aspects of the present disclosure are directed to a liquid cooling enclosure to house a system (e.g., a memory sub-system) and enable heat generated by one or more active components of the system to be effectively transferred out of the enclosure to a connector-side cold plate in a computing system. According to embodiments, the enclosure is configured to house a memory sub-system. The memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

Many enclosures, such as those containing Printed Circuit Board Assemblies (PCBAs) (e.g., memory sub-systems) often utilize thermal interface materials (TIM S) and external heat sinks for thermal dissipation. These enclosures typically adhere to industry standards for dimensions, form factors, durability, etc. that allow them to be used as rackmount servers in rackmount server systems. Conventional enclosures included in rackmount servers are nearly fully sealed, creating a condition of stagnant air within. TIM s can be dispensed on enclosed PCBAs to transfer heat from the integrated circuits (ICs) of the PCBA to the interior surface of the enclosure, from where it is eventually dissipated through the enclosure to heat dissipating fins of the external heat sink.

Other enclosures may be employed in a liquid cooling system where a cold plate is arranged at one of the enclosure. The cold plate (also referred to as a “cooling plate” or “liquid cold plate”) may be a metallic plate with a fluid circulating through which drains the heat from the active components of the system within the enclosure when the enclosure is mounted on the cold plate. In certain instances, the cold plate enables the localized cooling of heat-generating components of a system encased in an enclosure by transferring heat from the system to a liquid that flows to a remote heat exchanger and dissipates into either the ambient or to another liquid in a secondary cooling system.

In such systems, a cold plate is arranged along a length of the enclosure. Thermal contact between the cold plate and the enclosure housing the system (e.g., a sold-state drive or SSD) is achieved by sliding the enclosure into a slot along the enclosure-facing side of the cold plate. To optimize thermal contact between the cold plate and the enclosure, the cold plate includes portions of a malleable (e.g., gum-like) material (such as a flexible polymer) to allow the cold plate to conform to the surface of the enclosure. However, during the sliding of the enclosure against the cold plate, the material of the cold plate physically deforms in response to the sheer force of the sliding enclosure, preventing uniform contact along the length of the enclosure and inconsistent conduction of the heat of the system within the enclosure to the cold plate.

Aspects of the present disclosure address the above and other deficiencies of existing technologies by providing an enclosure having a cavity to house a system (e.g., a printed circuit board assembly (PCBA) such as a memory sub-system), the enclosure having one or more heat pipes arranged within a corresponding recess of one or more portions of the enclosure to conduct heat to a cold plate (e.g., a metal cold plate with cooling fluids flowing through flow paths). In an embodiment, the one or more heat pipes are composed of conductive materials (e.g., aluminum, copper, graphite, diamond, etc.). According to embodiments, the one or more heat pipes can include three portions: an evaporator section (e.g., a heat input/source), an adiabatic or transport section, and a condenser section (e.g., a heat output/sink). In an embodiment, the enclosure is arranged to make thermal contact with a cold plate located at the connector-end of the enclosure (i.e., an end of the enclosure that is facing a connector of a computing system when installed within the computing system).

In an embodiment, the enclosure may be composed of a metallic material (e.g., a heavy-duty metal construction). In an embodiment, the enclosure includes a first enclosure portion and a second enclosure portion that can be coupled together to form an internal cavity or housing for a system. In an embodiment, the enclosed system can include a memory sub-system. The memory sub-system can include components such as a memory device and a memory sub-system controller communicably coupled to the memory device. In an embodiment, the memory sub-system can be a storage device, a memory module, or a combination of a storage device and memory module, such as a solid-state drive (SSD). In an embodiment, a host system of the computing system can be coupled to the system (e.g., a memory sub-system such as an SSD drive) housed in the enclosure via the connector.

In an embodiment, an inner or interior surface of the first enclosure portion and the second enclosure portion include a recessed portion. The recessed portions of the first enclosure portion and the second enclosure portion are arranged facing the system enclosed within the internal cavity of the enclosure. According to embodiments, each recessed portion includes one or more heat pipes arranged along the interior surfaces of the first enclosure portion and second enclosure portion. Advantageously, the heat pipes conduct heat generated by the system along both the first enclosure portion and the second enclosure portion along the length of the enclosure toward the cold plate arranged at the connector-end of the enclosure.

Advantages of the present disclosure further include, but are not limited to, arrangement of the heat pipes within the corresponding recessed areas of both the first enclosure portion and the second enclosure portion results in increased surface area, which provides for increased contact area with the cold plate for increased conductivity of heat from the enclosed system. Advantageously, the larger contact area of the enclosure to the cold plate achieves increased thermal performance of the enclosed system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller, CXL controller). The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1 illustrates memory sub-system 110 as an example. In general, the host system 120 can access multiple memory sub-systems via a same communication connection, multiple separate communication connections, and/or a combination of communication connections. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not- and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SL Cs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

In one embodiment, the memory sub-system 110 is enclosed in an enclosure 113 including one or more heat pipes that enable heat generated by the one or more active components of the memory sub-system 110 conducted away from the memory sub-system 110 and to a cold plate arranged at a connector-end of the enclosure 113 (i.e., an end of the enclosure 113 facing a connector that enables coupling to the host system 120). In an embodiment, the enclosure 113 includes a first enclosure portion and a second enclosure portion. In an embodiment, the first enclosure portion includes a first recessed portion and the second enclosure portion includes a second recessed portion. In an embodiment, a first set of one or more heat pipes are arranged, embedded, affixed, or attached within the first recessed portion of the first enclosure portion. In an embodiment, a second set of one or more heat pipes are arranged embedded, affixed, or attached within the second recessed portion of the second enclosure portion. In an embodiment, each of the heat pipes is arranged along at least a portion of the length of a corresponding portion (i.e., first enclosure portion or second enclosure portion) of the enclosure 113. This arrangement of heat pipes in the enclosure 113 enables heat generated by components arranged along a length of the memory sub-system 110 to be conducted along the length of the enclosure 113 via the first set and second set of heat pipes. Further details with regards to the operations and functionality of enclosure 113 are described below.

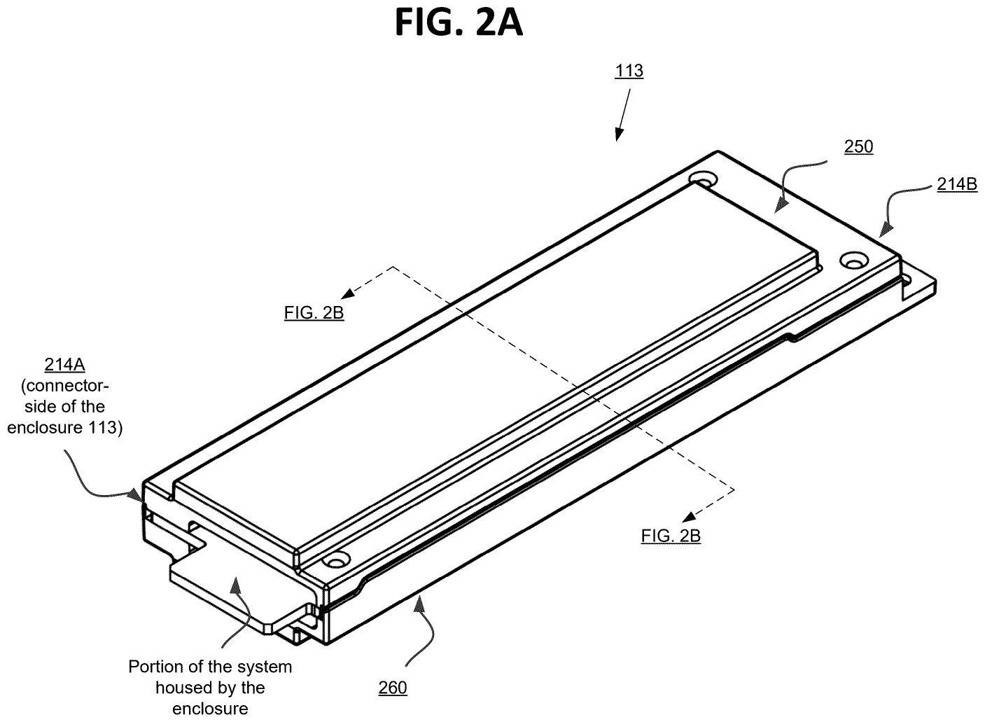

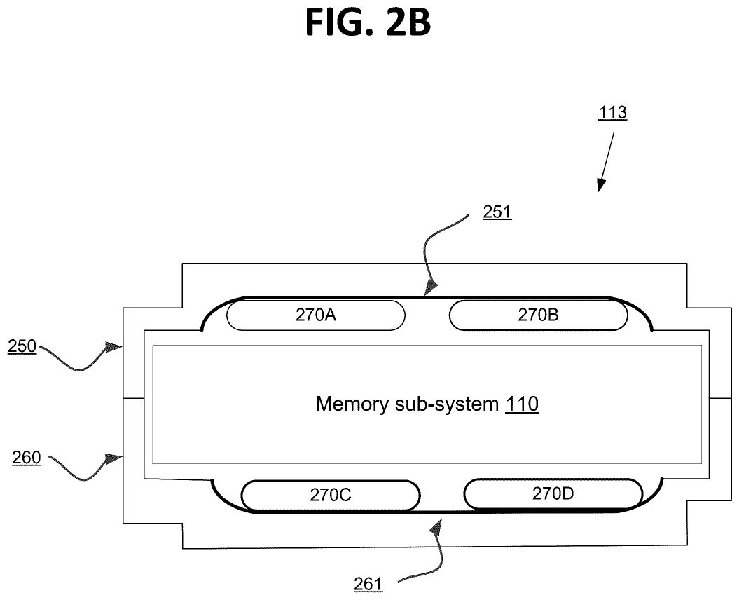

FIG. 2A illustrates a perspective view of an example enclosure 113 in accordance with one or more embodiments of the present disclosure. As illustrated, the enclosure 113 includes a first enclosure portion 250 coupled to a second enclosure portion 260. The coupling of the first enclosure portion 250 and the second enclosure portion 260 forms a cavity for enclosing a system (e.g., a memory sub-system such as memory sub-system 110 of FIG. 1). A portion of the enclosed or housed system extending from the enclosure 113 is illustrated in FIG. 2.

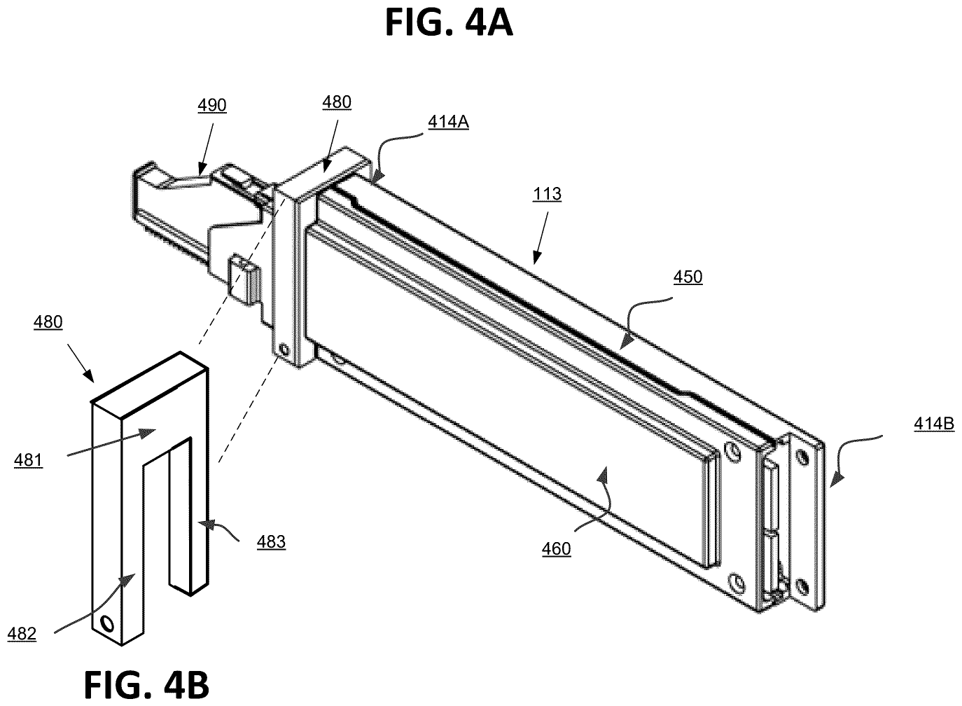

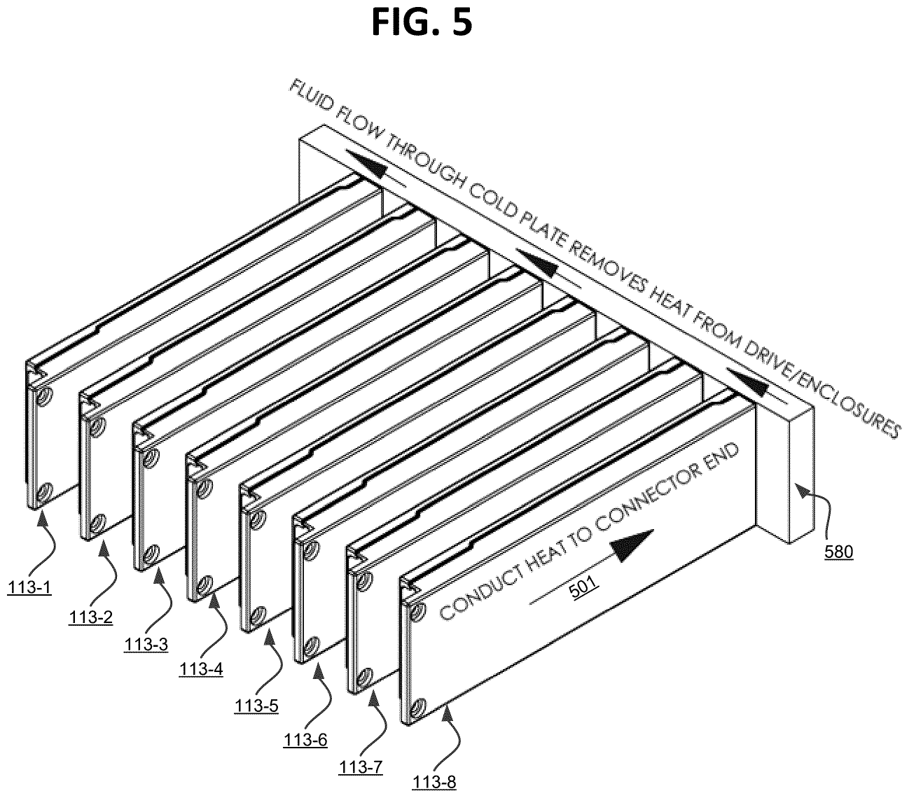

The enclosure 113 includes a first end 214A and a second end 214B. The first end 214A is configured to face a connector of a computing system (e.g., computing system 100 of FIG. 1) when the enclosed system (e.g., the memory sub-system 110) is installed for operation in association with a host system (e.g., host system 120 of FIG. 1). In an embodiment, the first end 214A or connector-side end of the enclosure 113 when installed in the computing system makes physical and thermal contact with a cold plate (shown in FIGS. 4 and 5) arranged at the connector-end of the enclosure 113.

FIG. 2B illustrates a cross-sectional view of the enclosure 113 of FIG. 2A (as denoted in FIG. 2A). As shown in FIG. 2B, the first enclosure portion 250 includes a first recessed portion 251 and the second enclosure portion includes a second recessed portion 261. In an embodiment, a first set of one or more heat pipes (heat pipes 270A and 270B in the example shown in FIG. 2B) are arranged within the first recessed portion 251 of the first enclosure portion 250 along a length of the enclosure 113. In an embodiment, a second set of one or more heat pipes (heat pipes 270C and 270D in the example shown in FIG. 2B) are arranged within the second recessed portion 261 of the second enclosure portion 260 along the length of the enclosure 113.

As illustrated in FIG. 2B, the heat pipes (270A, 270B, 270C, and 270D) arranged within the respective recessed portions (the first recessed portion 251 and the second recessed portion 261) are facing the enclosed memory sub-system 110 housed in the internal cavity of the enclosure 113. According to embodiments, the heat pipes (270A, 270B, 270C, and 270D) can utilize latent heat of vaporization to continuously manage electrical waste heat generated by the memory sub-system 110. In an embodiment, a cooling fluid within the respective heat pipes 270A-D vaporizes as it absorbs heat, and then moves toward the connector-side end of the enclosure 113 where the heat is conducted or released to the cold plate arranged at the connector-side end of the enclosure 113.

Advantageously, the heat pipes (270A, 270B, 270C, and 270D) conduct heat generated by components arranged along a length of the memory sub-system 110 to the connector-side end of the enclosure 113 (i.e., the first end 214A, as shown in FIG. 2A) where the cold plate is arranged. In addition, embedding the heat pipes in the recessed portions of the enclosure 113 results in an increase in the thermal contact area of the enclosure 113 to the cold plate arranged at the connector-side end of the enclosure 113.

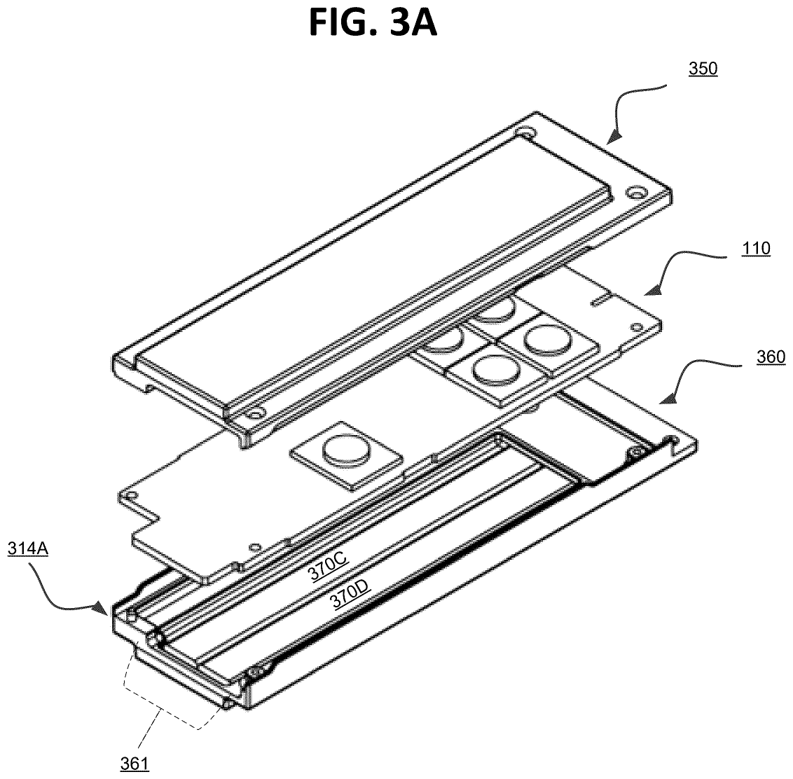

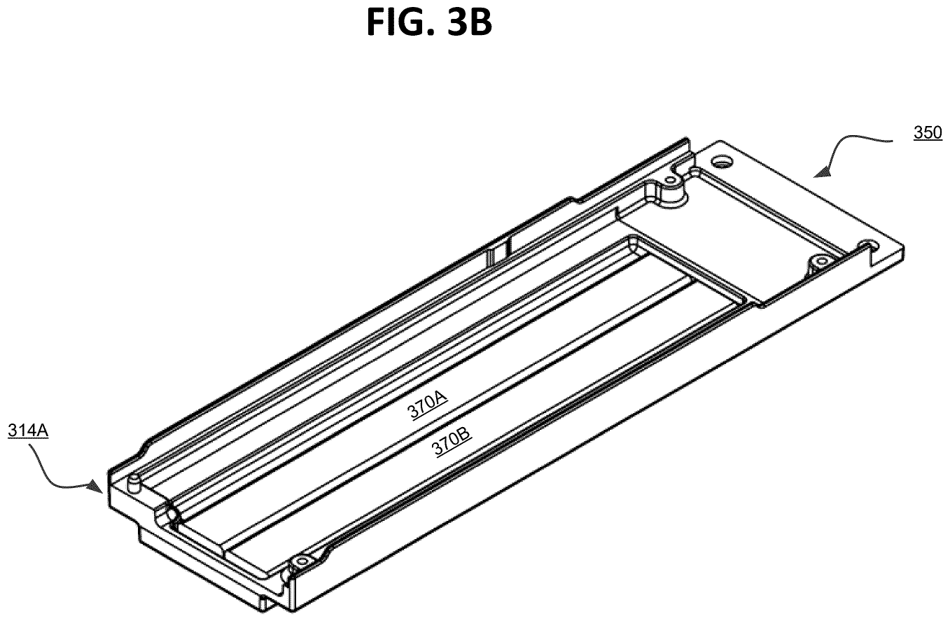

FIG. 3A illustrates an expanded view of an example enclosure, according to embodiments of the present disclosure. As shown in the expanded view of FIG. 3A, the enclosure includes the first enclosure portion 350 and the second enclosure portion 160 which, when coupled, form a cavity for housing an example memory sub-system 110. As shown in FIG. 3B, the second enclosure portion 360 includes an inner surface having a recessed portion 361. In an embodiment, the recessed portion 361 is arranged length-wise along the second enclosure portion 360. According to embodiments, the heat generated by the memory sub-system 110 is conducted by the heat pipes 370C, 370D toward a connecter-side end 314A of the enclosure, when the enclosure is installed within a computing system (e.g., computing system 100 of FIG. 1).

FIG. 3B illustrates a perspective view of the example first enclosure portion 350 of FIG. 3A. As shown in FIG. 3B, a set of heat pipes including heat pipe 370A and 370B is arranged within the recessed portion 351 of the first enclosure portion 350. As shown, the heat pipes 370A and 370B are arranged along a length of the first enclosure portion 350 and face toward the internal cavity housing the memory sub-system 110. According to embodiments, the heat pipes 370A and 370B are arranged to move heat generated by the components of the memory sub-system 110 along the length of the first enclosure portion 360. According to embodiments, the heat generated by the memory sub-system 110 is conducted by the heat pipes 370A, 370B toward the connecter-side end 314A of the enclosure, when the enclosure is installed in the computing system (e.g., computing system 100 of FIG. 1).

Advantageously, the heat pipes 370A-370D of FIGS. 3A and 3B provide a length-wise thermal contact area with the memory sub-system 110 to manage heat generated by active components positioned along the length of the surfaces (e.g., top and bottom surfaces) of the memory sub-system 110.

Although the examples shown in FIGS. 3A and 3B illustrate a first set of two heat pipes (370A and 370B) arranged within the recessed portion 351 of the first enclosure portion 350 and a second set of two heat pipes (370C and 370D) arranged within the recessed portion 361 of the second enclosure portion 360, it is to be appreciated that any number of heat pipes may be employed). For example, one or more heat pipes may be embedded or coupled within the recessed portion 351 and one or more heat pipes may be embedded or coupled within the recessed portion 361.

FIG. 4A illustrates a perspective view of an example enclosure 113 housing a memory sub-system (not shown) arranged within a computing system including a connector 490. In an embodiment, the connector 490 enables coupling of the memory sub-system 113 enclosed within the enclosure 113 to a host system (e.g., host system 120 of FIG. 1). According to embodiments, the enclosure 113 includes a first enclosure portion 450 and a second enclosure portion 460 that form a cavity or internal housing for the memory sub-system. As illustrated, the enclosure 113 includes a first end 414A and a second end 414B, where the first end 414A (i.e., the connector-facing side) of the enclosure 113 is in contact with a cold plate 480.

According to embodiments, the cold plate 480 (also referred to as a cooling plate or liquid cold plate) is a metallic plate with a fluid circulating through. As illustrated in FIG. 4A, the first end 414A of the enclosure 113 is in physical and thermal contact with the cold plate 480. Due to the configuration of the enclosure 113, the surface area of the connector-facing first end 414A enables increased contact with the cold plate 480, which results in improved thermal conduction from the enclosure 113 to the cold plate 480.

FIG. 4B illustrates an isolated perspective view of an example cold plate 480, according to embodiments of the present disclosure. In an embodiment, a portion of the internally housed memory sub-system can extend via the slot of the cold plate 480 and into coupling with the connector 490 of the computing system (e.g., a connector to a host system, such as host system 120 of FIG. 1). In the example shown in FIG. 4B, the connector-facing surfaces of the first end 414A of the first enclosure portion 450 and the second enclosure portion 460 make contact with at least a portion of an enclosure-facing surface of the cold plate 480. For example, the connector-facing surface of the first end 414A of the enclosure 113 makes contact with at least a portion of surface regions 481, 482, and 483 of the cold plate 480. As described above with reference to FIG. 2B, the recessed portions of the first enclosure portion 450 and the second enclosure portion 460 provide for increased contact area of the enclosure 113 with respect to surface regions 482 and 483 of the cold plate 480.

In an embodiment, the contact area between the cold plate 480 and the enclosure 113 (e.g., contact between the enclosure 113 and at least portions of surface regions 481, 482, and 483) enables the fluid of the cold plate 480 to drain the heat from enclosure 113. Accordingly, heat generated by the memory sub-system housed in the enclosure 113 is conducted via the one or more heat pipes arranged within the respective recessed portions of the first enclosure portion and the second enclosure portion. Advantageously, this heat conducts via the heat pipes of the enclosure 113 to the cold plate 480.

FIG. 5 illustrates a perspective view of an example computing system including a set of multiple enclosures (e.g., 113-1, 113-2, 113-3, 113-4, 113-5, 113-6, 113-7, and 113-8), each housing a system (e.g., a memory sub-system), according to embodiments of the present disclosure. As shown in FIG. 5, each enclosure (enclosure 113-1, 113-2 . . . 113-8) is in contact with a cold plate 580 arranged at a connector-end of the respective enclosure. As illustrated, heat generated by components of the system housed in each enclosure is conducted via the heat pipes (not shown in FIG. 5) arranged within the respective recessed portions (e.g., a first recessed portion of a first enclosure portion and a second recessed portion of a second enclosure portion of the enclosure, as described in detail above). As denoted by arrow 501, the heat generated by the enclosed system is conducted via the set of heat pipes to the cold plate 580 located at the connector end of the enclosure (e.g., enclosure 113-8). As illustrated, a fluid flows through the cold plate 580 and removes the system-generated heat from each enclosure (enclosure 113-1, 113-2 . . . 113-8).

In embodiments, enclosures described with respect to FIGS. 1-5 can have dimensions and form factors that conform to an established standard. For example, enclosure 113 can meet the specifications set by standards such as the Storage Networking Industry Association (SNIA) SSD form factor standard, the National Electrical Manufacturers Association (NEMA) enclosure rating, the Electronic Industries Alliance/Telecommunications Industry Association (EIA/TIA) standards for telecommunications equipment, the Advanced Technology eXtended (ATX) form factor standard, the Micro-ATX form factor standard, Serial ATA International Organization (SATA-10) standards (e.g., U.2 standard), Peripheral Component Interconnect Special Interest Group (PCI-SIG) standards (e.g., M.2 standard), Institute of Electrical and Electronics Engineers (IEEE) standards, and/or the like. In some embodiments, enclosure 300A can conform to any necessary standard, ensuring compatibility within varied systems (e.g., data centers, consumer electronics, etc.).

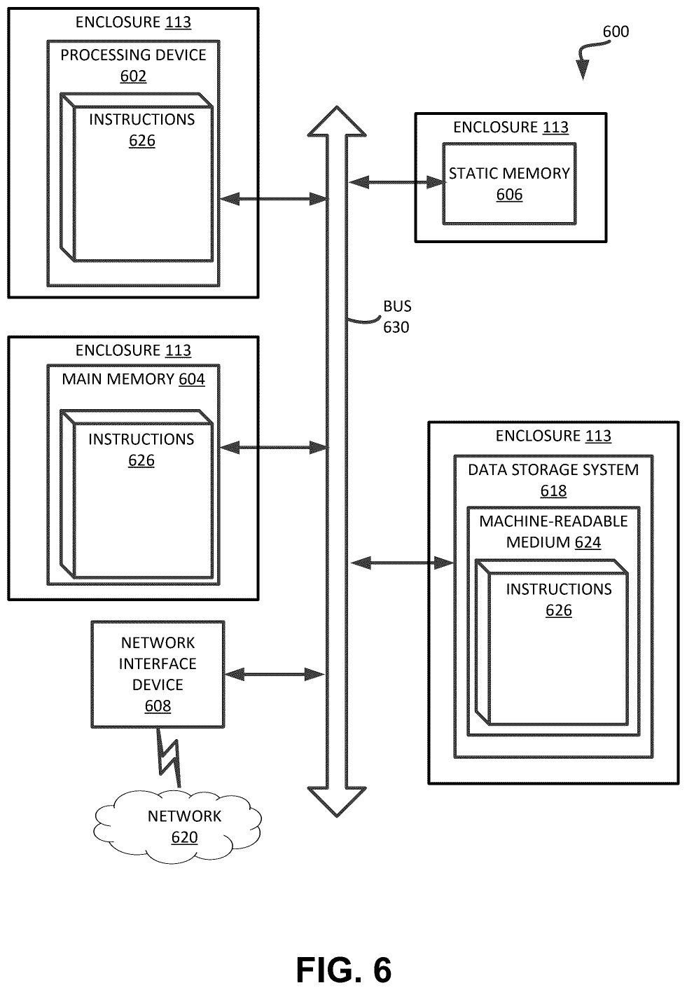

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the local media controller 135 and/or memory subsystem controller 115 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRA M) such as synchronous DRAM (SDRAM) or RDRAM, etc.), a static memory 606 (e.g., flash memory, static random access memory (SRAM), etc.), and a data storage system 618, which communicate with each other via a bus 630. In some embodiments, at least one of processing device 602, main memory 604, static memory 606, or data storage system 618 are enclosed in an enclosure (e.g., enclosure 113 of FIG. 1) for passive thermal cooling.

Processing device 602 represents one or more general-purpose processing devices such as a microprocessor, a central processing unit, or the like. M ore particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to a controller (e.g., local media controller 135 and/or memory sub-system controller 115 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROM s, and magnetic-optical disks, read-only memories (ROM s), random access memories (RAM s), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An enclosure comprising:
a first enclosure portion comprising a first recessed portion;
a first set of one or more heat pipes arranged within the first recessed portion;
a second enclosure portion comprising a second recessed portion; and
a second set of one or more heat pipes arranged within the second recessed portion, wherein the first enclosure portion and the second enclosure portion form a cavity to house a memory sub-system, and wherein heat generated by the memory sub-system is conducted via the first set of one or more heat pipes and the second set of one or more heat pipes to a first end of the enclosure.

2. The enclosure of claim 1, wherein the first end of the enclosure comprises a surface configured to contact a cold plate.

3. The enclosure of claim 1, wherein a portion of the memory sub-system adapted for coupling with a connector of a computing system extends from the enclosure.

4. The enclosure of claim 1, wherein the first set of one or more heat pipes is arranged along at least a portion of a length of the first enclosure portion.

5. The enclosure of claim 1, wherein the second set of one or more heat pipes is arranged along at least a portion of a length of the second enclosure portion.

6. A system comprising:
a host system coupled to a connector; and
an enclosure comprising a memory sub-system coupled to the host system via the connector; wherein the enclosure comprises:
a first enclosure portion comprising a first recessed portion;
a first set of one or more heat pipes arranged within the first recessed portion;
a second enclosure portion comprising a second recessed portion; and
a second set of one or more heat pipes arranged within the second recessed portion, wherein heat generated by the memory sub-system is conducted via the first set of one or more heat pipes and the second set of one or more heat pipes to a first end of the enclosure.

7. The system of claim 6, further comprising a cold plate located at the first end of the enclosure.

8. The system of claim 7, wherein at least a portion of the heat conducted via the first set of one or more heat pipes and the second set of one or more heat pipes is removed from the enclosure by the cold plate.

9. The system of claim 7, wherein the cold plate comprises a fluid, wherein the fluid flows through the cold plate and removes at least a portion of the heat from the enclosure.

10. The system of claim 6, wherein the first end of the enclosure faces the connector.

11. The system of claim 10, wherein at least a portion of a surface of the first end of the enclosure contacts at least a portion of a cold plate.

12. The system of claim 6, wherein the first set of one or more heat pipes comprises a first heat pipe and a second heat pipe.

13. The system of claim 12, wherein the second set of one or more heat pipes comprises a third heat pipe and a fourth heat pipe.

14. The system of claim 6, wherein the first set of one or more heat pipes is arranged along at least a portion of a length of the first enclosure portion.

15. The system of claim 6, wherein the second set of one or more heat pipes is arranged along at least a portion of a length of the second enclosure portion.

16. The system of claim 6, wherein the memory sub-system comprising a memory device and a memory sub-system controller communicably coupled to the memory device.

17. An apparatus comprising:
an enclosure to enclose at least a portion of a memory sub-system, wherein the enclosure comprises:
a first enclosure portion comprising a first recessed portion;
a first set of one or more heat pipes arranged within the first recessed portion;
a second enclosure portion comprising a second recessed portion; and
a second set of one or more heat pipes arranged within the second recessed portion, wherein heat generated by the memory sub-system is conducted via the first set of one or more heat pipes and the second set of one or more heat pipes to a first end of the enclosure.

18. The apparatus of claim 17, wherein the first end of the enclosure comprises a surface configured to contact a cold plate.

19. The apparatus of claim 18, wherein at least a portion of the heat conducted via the first set of one or more heat pipes and the second set of one or more heat pipes is removed from the enclosure by the cold plate.

20. The apparatus of claim 17, wherein the first set of one or more heat pipes is arranged along at least a portion of a length of the first enclosure portion, and wherein the second set of one or more heat pipes is arranged along at least a portion of a length of the second enclosure portion.
